(19) United States
(12) Patent Application Publication
(10) Pub. No.: US 2025/0328161 A1
(43) Pub. Date: Oct. 23, 2025

(54) Clock synchronization control optimization

(71) Applicant: Mellanox Technologies, Ltd., Yokneam (IL)

(72) Inventors: Hanan Shteingart, Herzliya (IL); Thomas Kernen, Geneva (CH); Maciej Machnikowski, Reda (PL); Gil Shabat, Hod Hasharon (IL)

(21) Appl. No.: 18/914,327

(22) Filed: Oct. 14, 2024

Related U.S. Application Data
(60) Provisional application No. 63/634,939, filed on Apr. 17, 2024.

(51) Int. Cl. G06F 1/12; G06F 1/10; G06N 7/01

(52) U.S. Cl. CPC G06F 1/12; G06F 1/10; G06N 7/01

(57) ABSTRACT

In one embodiment, a device includes a processing unit to find at least one value of at least one filter parameter using Bayesian Optimization, and provide the at least one value of the at least one filter parameter to a filter to generate an adjustment to cause clock circuitry to adjust a local clock signal or local clock based on an error signal and the at least one value of the at least one filter parameter, and a memory to store data used by the processing unit.

### RELATED APPLICATION INFORMATION

The present application claims benefit of US Provisional Patent Application S/N 63/634,939 of Shteingart, et al., entitled “Optimizing the PTP Control Loop”, filed 17 Apr. 2024, the disclosure of which is hereby incorporated herein by reference.

### FIELD OF THE DISCLOSURE

The present disclosure relates to computer systems, and in particular, but not exclusively to, clock synchronization.

### BACKGROUND

Clock synchronization among network devices is used in many network applications. One application of using a synchronized clock value is for measuring one-way latency from one device to another device. If the clocks are not synchronized the resulting one-way latency measurement will be inaccurate.

Synchronization is typically achieved by syntonization, in which the clock frequency of two devices is aligned, and aligning the phase between the two devices.

For Ethernet, there are two complementary methods to achieve synchronization. One is Synchronous Ethernet (SyncE), which is a physical-layer protocol which achieves syntonization based on the receive/transmit symbol rate. SyncE is an International Telecommunication Union Telecommunication (ITU-T) Standardization Sector standard for computer networking that facilitates the transference of clock signals over the Ethernet physical layer. In particular, SyncE enables clock syntonization inside a network with respect to a master clock.

The other is Precision Time Protocol (PTP), which is a packet-based protocol that may be used with SyncE to align offset and phase between two clocks. PTP is used to accurately synchronize clocks throughout a computer network. PTP is an example of a two-way time synchronization protocol. A two-way time synchronization protocol uses time synchronization packets which are exchanged in both directions between a clock leader and a clock follower.

A remote clock frequency from a remote clock may be recovered (e.g., using SyncE) or remote time (e.g., using PTP) and compared to the local clock providing an error signal. PTP and Sync-E implementations use feedback systems (e.g., with a loop filter or servo filter) to steer the local clock frequency and time iteratively towards a recovered remote master time and frequency, respectively. The filter corrects local oscillator frequency variations based on the error signal. The filter may also determine how fast the error should be corrected. In some cases, the 10 filter not only looks at the current error but also the integral of the error (which provides the cumulative error). The performance of the filter is governed by filter parameters which are set by the device designer and may determine how quickly the clock error is corrected.

### SUMMARY

There is provided in accordance with still another embodiment of the present disclosure, a device, including a processing unit to find at least one value of at least one filter parameter using Bayesian Optimization, and provide the at least one value of the at least one filter parameter to a filter to generate an adjustment to cause clock circuitry to adjust a local clock signal or local clock based on an error signal and the at least one value of the at least one filter parameter, and a memory to store data used by the processing unit.

Further in accordance with an embodiment of the present disclosure, the device includes the clock circuitry including an oscillator to generate the local clock signal having a clock frequency, and a hardware clock to maintain the local clock based on the local clock signal, the filter to receive the error signal between a received remote clock and the local clock, and generate the adjustment to cause the clock circuitry to adjust the local clock signal or the local clock based on the error signal and the at least one value of the at least one filter parameter.

Still further in accordance with an embodiment of the present disclosure the clock circuitry includes an oscillator to generate the local clock signal having a clock frequency, and a hardware clock to maintain the local clock based on the local clock signal, the filter is to receive the error signal between a received remote clock and the local clock, and generate an adjustment to cause the clock circuitry to adjust the local clock signal or the local clock based on the error signal and the at least one value of the at least one filter parameter.

Additionally in accordance with an embodiment of the present disclosure the processing unit is to dynamically change the at least one value of the at least one filter parameter in order to find the at least one value of the at least one filter parameter which improves the adjustment of the local clock signal or local clock.

Moreover in accordance with an embodiment of the present disclosure the processing unit is to select different parameter value sets, each parameter value set including at least one respective filter parameter value, provide the different parameter value sets to the filter for the filter to operate the different parameter value sets, receive measurements of error between a received remote clock and the local clock for corresponding ones of the different parameter value sets, build a model based on the received measurements of error and the corresponding different parameter value sets, build an acquisition function from the model, find a new parameter value set including at least one new parameter value of the at least one filter parameter based on the acquisition function, receive a new measurement of error between the received remote clock and the local clock for the new parameter value set, update the model based on the new measurement of error and the new parameter value set, and further improve the model based on further new parameter value sets and corresponding new measurements.

Further in accordance with an embodiment of the present disclosure the processing unit is to select the new parameter value set based on statistics provided from the model.

Still further in accordance with an embodiment of the present disclosure the model is a Gaussian Process model.

Additionally in accordance with an embodiment of the present disclosure the measurements of error are root mean square error measurements of corresponding sections of an error signal between the received remote clock and the local clock.

There is also provided in accordance with another embodiment of the present disclosure, a system, including at least one processing unit to manage optimization of at least one value of at least one filter parameter of respective ones of devices an order of the devices along a logical clock synchronization topology, and at least one memory to store data used by the at least one processing unit, wherein the devices are to distribute a master clock over a network along the logical clock synchronization topology in order to synchronize the devices to the master clock, and each of the devices includes clock circuitry including an oscillator to generate a local clock signal having a clock frequency, and a hardware clock to maintain a local clock based on the local clock signal, and a filter to receive an error signal between a received remote clock and the local clock, and generate an adjustment to cause the clock circuitry to adjust the local clock signal or the local clock based on the error signal and the at least one value of the at least one filter parameter.

Moreover, in accordance with an embodiment of the present disclosure, the system includes the devices.

Further in accordance with an embodiment of the present disclosure the devices include a first device, a second device, and a third device, the second device is to clock synchronize to the first device, the third device is to clock synchronize to the second device, and the at least one processing unit is to manage optimization of the at least one filter parameter of the respective devices such that the at least one processing unit is to complete optimization of the at least one value of the at least one filter parameter of the first device, and then commence optimization of the at least one value of the at least one filter parameter of the second device, and then commence optimization of the at least one value of the at least one filter parameter of the third device after completion of optimization of the optimization of the at least one value of the at least one filter parameter of the second device.

Still further in accordance with an embodiment of the present disclosure the third device is an end-node host device.

Additionally in accordance with an embodiment of the present disclosure the devices include a first device, a second device, and a third device, the second device is to clock synchronize to the first device, the third device is to clock synchronize to the second device, and the at least one processing unit is to manage optimization of the at least one filter parameter of the respective devices such that the at least one processing unit is to commence optimization of the at least one value of the at least one filter parameter of the first device, and then commence optimization of the at least one value of the at least one filter parameter of the second device, and then commence optimization of the at least one value of the at least one filter parameter of the third device.

Moreover in accordance with an embodiment of the present disclosure the logical clock synchronization topology includes sub-paths after a main clock synchronization path, and the at least one processing unit is to manage optimization of the at least one value of the at least one filter parameter of the devices on one of the sub-paths independently of optimization of the at least one value of the at least one filter parameter of the devices on a different one of the sub-paths.

Further in accordance with an embodiment of the present disclosure the at least one processing unit is to optimize in parallel the at least one value of the at least one filter parameter of at least two of the devices on different ones of the sub-paths.

Still further in accordance with an embodiment of the present disclosure the devices include any one or more of the following a network switch, or an end-node host device.

Additionally in accordance with an embodiment of the present disclosure the at least one processing unit it to manage re-optimization of the at least one value of the at least one filter parameter of a given device of the devices, and ones of the devices downstream from the given device with respect to the logical clock synchronization topology, in response to a triggering event being identified in the given device, the re-optimization being managed the order of the given device and the downstream devices along the logical clock synchronization topology.

Moreover, in accordance with an embodiment of the present disclosure the at least one processing unit is to manage the optimization of the at least one value of the at least one filter parameter of the respective devices while the master clock is being distributed among the respective devices.

Further in accordance with an embodiment of the present disclosure the at least one processing unit is optimize the at least one value of the at least one filter parameter of the respective devices using Bayesian Optimization.

There is also provided in accordance with still another embodiment of the present disclosure, a method, including finding at least one value of at least one filter parameter using Bayesian Optimization, and providing the at least one value of the at least one filter parameter to a filter to generate an adjustment to cause clock circuitry to adjust a local clock signal or local clock based on an error signal and the at least one value of the at least one filter parameter.

There is also provided in accordance with yet still another embodiment of the present disclosure, a method, including managing optimization of at least one value of at least one filter parameter of respective ones of devices an order of the devices along a logical clock synchronization topology, and distributing a master clock over a network along the logical clock synchronization topology in order to synchronize the devices to the master clock.

### BRIEF DESCRIPTION OF THE DRAWINGS

The present disclosure will be understood from the following detailed description, taken in conjunction with the drawings in which:

FIG. 1 is a block diagram view of a network device constructed and operative in accordance with an embodiment of the present disclosure;

FIG. 2 is a flowchart including steps in a clock synchronization method for use with the device of FIG. 1;

FIG. 3 is a flowchart including steps in a filter value selection method using Bayesian Optimization for use with the device of FIG. 1;

FIG. 4 is a block diagram view of a clock synchronization system constructed and operative in accordance with an embodiment of the present disclosure;

FIG. 5 is a flowchart including steps in a system-wide filter value optimization method in the system of FIG. 4; and

FIG. 6 is a schematic view of a datacenter in the system of FIG. 1 constructed and operative in accordance with an embodiment of the present disclosure.

### DESCRIPTION OF EXAMPLE EMBODIMENTS

### Overview

Precision Time Protocol (PTP) allows a device to optimize a certain number of filter parameter values in the PTP control loop which improves the accuracy and stability of the time transfer. Finding the optimal parameters is very time consuming and particularly challenging when a network includes multiple nodes that need optimization and may depend on various factors including the hardware being used, the link(s) over which time transfer is occurring, control loop characteristics which are outside the PTP specification and may be designed per PTP stack, and environmental factors such as temperature and vibrations which may affect the operation of the oscillator on a device. Even when optimal values have been found, if the time reference (e.g., the currently selected PTP grandmaster) changes (e.g., due to failure of the previous grandmaster), the values of the parameters in each device may need changing as well.

Embodiments of the present disclosure address at least some of the above drawbacks by providing a system and method that efficiently automates the discovery of optimal values of the filter parameters. One aspect of the invention manages optimization of the values of the filter parameters device-by-device starting from a root device in a logical clock synchronization topology and then moving downstream to other devices in the topology because optimizations performed downstream are impacted by optimizations performed upstream in the logical clock synchronization topology. For example, if device B is clock synchronized (i.e., receives a master clock) from device A, and device C from device B, the value(s) of the filter parameter(s) of device A are optimized, and once optimized, the value(s) of the filter parameter(s) of device B are optimized, and once optimized, the value(s) of the filter parameter(s) of device C are optimized, and so on.

In some embodiments, the logical clock synchronization topology may include sub-paths. For example, device C may pass the master clock to devices D1 and E1, and device D1 is the first device in a first sub-path including devices D2 and D3, and device E1 is the first device in a second sub-path including device E2. In such a case, the values of the filter parameters of devices D1 and E1 may be optimized at the same time. Once the value(s) of the filter parameter(s) of device D1 are optimized, the value(s) of the filter parameter(s) of device D2 are optimized, and so on. Similarly, once the value(s) of filter parameter(s) of device E1 are optimized, the value(s) of the filter parameter(s) of device E2 are optimized, and so on. The timing and ordering of the optimization of the value(s) of the filter parameters of devices in different sub-paths are independent of each other and may be parallelized, if possible. For example, timing and ordering of the optimization of the value(s) of the filter parameters of devices D1, D2, and D3 may be performed independently (i.e., irrespective of) the timing and ordering of the optimization of the value(s) of the filter parameters of devices E1, and E2.

The devices may include any suitable devices such as one or more network switches and/or one or more host devices with multiple Ethernet connections. The values of the filter parameters may be optimized using any suitable optimization method.

In some implementations, each time a filter parameter value is changed, the whole PTP stack is restarted, and time is needed for the whole system to settle. As the measurements may be noisy, each measurement may be taken multiple times, e.g., 5 times, and an average or median value, and variance is taken. For illustration purposes only, based on each individual measurement taking 10 minutes, the effective time for measurement is 50 minutes. Therefore, it is important to have an efficient method to optimize the value(s) of the filter parameter(s) of each device, especially when multiple devices are being optimized and are subject to an ordering of the optimization process as described above. In some embodiments, the values of the filter parameters are optimized using Bayesian Optimization, which provides an efficient method for finding value(s) of the filter parameter(s). Other optimization methods may be used, for example, a suitable machine learning method such as multiarmed bandits.

Bayesian Optimization is a statistical method using exploration and exploitation. The method may commence by testing random configurations with random sets of control loop parameter values, for example, with 5 random iterations. At each iteration, data extracted (e.g., root mean square (RMS) value) from the error signal is used to define the result(s) of the iteration with the value(s) of the filter parameter(s) used in that iteration. The data collected from the random iterations may be used to build a surrogate model (e.g., Gaussian model) so that for a given new configuration, the model provides the expected mean and expected variance. The method includes building an acquisition function of the surrogate model that provides value(s) for the next configuration, i.e., the value(s) of the filter parameter(s) to be used in the next iteration of the control loop. The acquisition function may control the tradeoff between exploration and exploitation. The device is run with the new value(s) of the parameters and the result(s) of the new iteration are extracted and the model is update for the new iteration and a new acquisition function is built from the updated model to provide value(s) for the next configuration. This may be repeated until a minimal error signal is achieved or a given number of rounds (e.g., 20-25 iterations) are processed.

### System Description

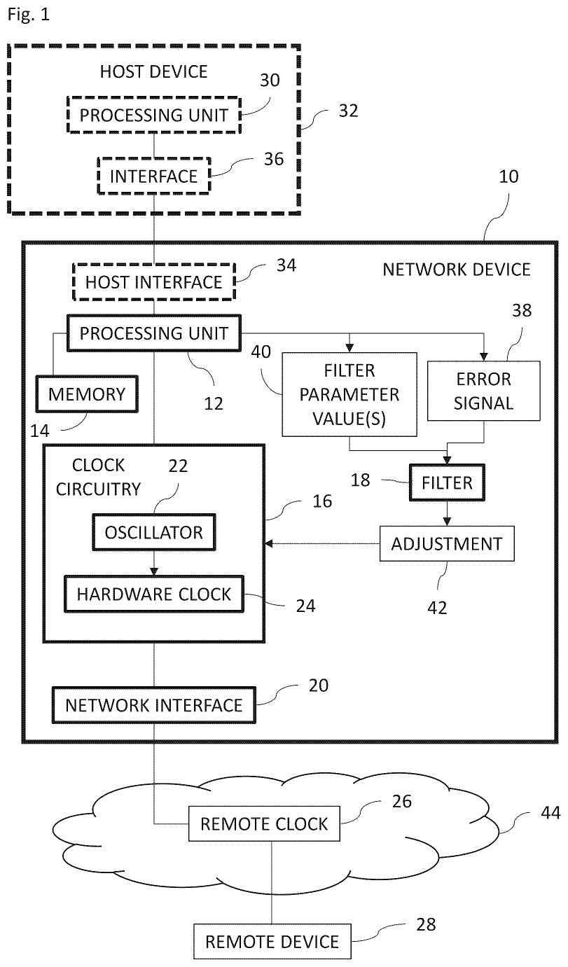

Reference is now made to FIG. 1, which is a block diagram view of a network device 10 constructed and operative in accordance with an embodiment of the present disclosure. The network device 10 includes a processing unit 12, a memory 14, clock circuitry 16, a filter 18, and a network interface 20. The processing unit 12 may be any suitable processing unit, for example, a central processing unit (CPU), a hardware processor configured using firmware, a data processing unit (DPU) including one or more processing cores. The memory 14 is configured to store data used by the processing unit 12. The clock circuitry 16 includes an oscillator 22 and a hardware clock 24. The oscillator 22 is configured to generate a local clock signal having a clock frequency. The hardware clock 24 is configured to maintain the local clock based on the local clock signal.

The network interface 20 is configured to receive a remote clock 26 from a remote device 28 over a network 44. The remote clock 26 may be a clock frequency and/or a clock value (e.g., a time-of-day value). The remote clock 26 may be received as a clock signal or based on clock synchronization messages, such as PTP messages, exchanged between network device 10 and the remote device 28.

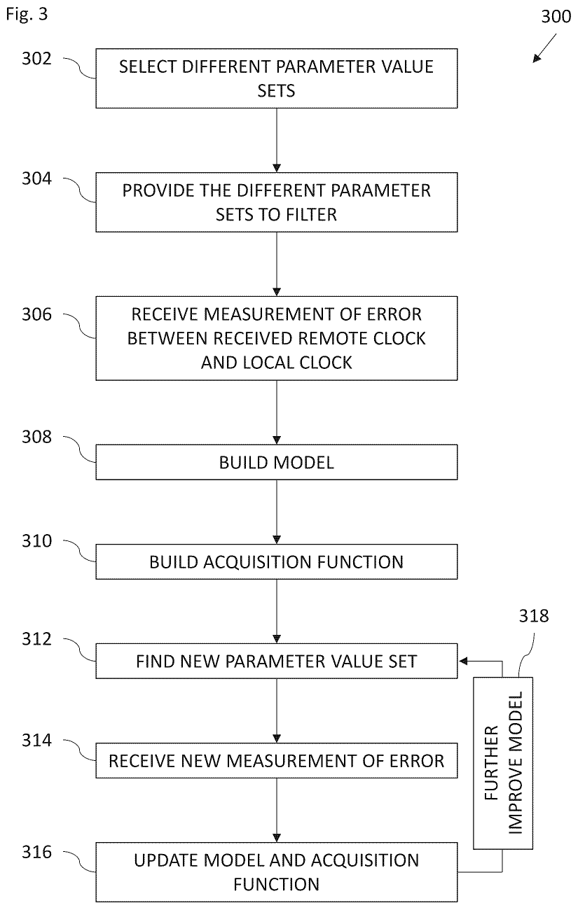

In some embodiments, the clock circuitry 16 may include time stamping circuitry (not shown) to timestamp the clock synchronization messages. The timed stamped clock synchronization messages or the received clock signal may then be processed by the processing unit 12 or another processing unit such as a processing unit 30 disposed in a host device 32 connected to network device 10 via a suitable data communication bus, such as a Peripheral Component Interconnect Express (PCIe) data communication bus. The processing unit 12 or the processing unit 30 may generate an error signal 38 representative of a clock difference between the local clock and/or local clock signal and the remote clock 26. The network device 10 may include a host interface 34 to share data with the host device 32 via an interface 36 of host device 32. The filter 18 is configured to receive one or more filter parameter values 40 and error signal 38 and provides one or more adjustments 42 to clock circuitry 16 to adjust the local clock signal or local clock, as described in more detail with reference to FIG. 3.

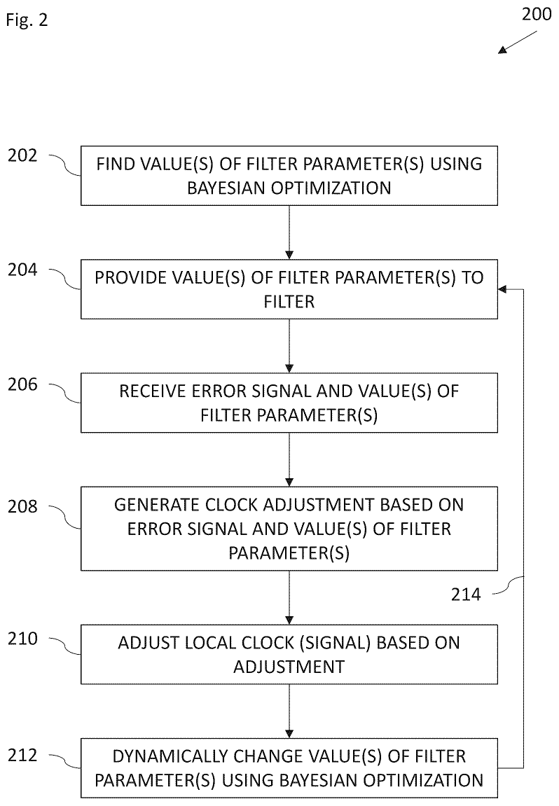

Reference is now made to FIG. 2, which is a flowchart 200 including steps in a clock synchronization method for use with the device 10 of FIG. 1. Reference is also made to FIG. 1. Some of the steps of the clock synchronization method of FIG. 2 are described as being performed by processing unit 12. In some embodiments, one or more of the steps described as being performed by processing unit 12 may be performed by any suitable processor, such as processing unit 30, or a remote processor (e.g., in a cloud computing solution), or by any suitable combination of processors.

The processing unit 12 is configured to find value(s) of one or more filter parameters using Bayesian Optimization (block 202). The step of block 202 is described in more detail with reference to FIG. 3. The processing unit 12 is configured to provide the found value(s) of the filter parameter(s) to filter 18 in order for the filter 18 to generate adjustment(s) 42 to cause clock circuitry 16 to adjust the local clock signal or the local clock based on the provided error signal 38 and value(s) of the filter parameter(s) (block 204).

The filter 18 is configured to receive: the error signal 38 between the received remote clock 26 and the local clock; and the found value(s) of the filter parameter(s) (block 206). The filter 18 may be any suitable filter. In some embodiments, the filter 18 may be a PI servo/filter with parameters P and I defining the filter bandwidth. The filter 18 is configured to generate adjustment(s) 42 to cause the clock circuitry 16 to adjust the local clock signal or the local clock based on the error signal 38 and the found value(s) of the filter parameter(s) (block 208). The filter 18 is configured to correct local oscillator frequency variations. The filter 18 also determines how fast the error should be corrected. In some cases, the filter 18 not only looks at the current error but also the integral of the error (which provides the cumulative error).

The clock circuitry 16 is configured to receive the adjustment(s) 42 and adjust a value of the local clock and/or a frequency of the local clock signal based on the adjustment(s) 42 to synchronize the local clock to the remote device 28 (block 210). The clock circuitry 16 may include circuitry such as a phase locked loop (PLL) (not shown) and/or a digitally controlled oscillator (DCO) and/or a network synchronizer to affect the adjustment to the local clock and/or local clock signal. An example of a suitable network synchronizer is Ultra-Low Jitter Network Synchronizer Clock LMK05318 commercially available from Texas Instruments Inc., 12500 TI Boulevard, Dallas, Texas 75243, USA. The DCO may provide a local clock signal with low phase noise and good drift stability and may be controlled by digital control signals/commands. The DCO may include a temperature-compensated crystal oscillator (TCXO) and generate an output frequency of around 156.25 MHz. SiT5377 is a ±100 ppb precision MEMS Super-TCXO and is suitable for use as the DCO. SiT5377 is commercially available from SiTime Corporation, 5451 Patrick Henry Drive, Santa Clara, CA 95054, USA.

The processing unit 12 is configured to dynamically change the value(s) of the filter parameter(s) in order to find the value(s) of the filter parameter(s) which improves the adjustment(s) of the local clock signal or local clock (block 212). The steps of blocks 204-212 are repeated (arrow 214) to improve the performance of the filter 18 and yield a reduced error signal 38.

Reference is now made to FIG. 3, which is a flowchart 300 including steps in a filter value selection method using Bayesian Optimization for use with the device 10 of FIG. 1. Reference is also made to FIG. 1. Some of the steps of the Bayesian Optimization method of FIG. 3 are described as being performed by processing unit 12. In some embodiments, one or more of the steps described as being performed by processing unit 12 may be performed by any suitable processor, such as processing unit 30, or a remote processor (e.g., in a cloud computing solution), or by any suitable combination of processors.

The processing unit 12 is configured to select, e.g., randomly, different parameter value sets (block 302). A suitable number (for example, 5 or 6) of the parameter value sets may be generated/selected. Each parameter value set includes one or more respective filter parameter values. If there are more than one value in each set, the values in a given set may be the same or different, and one value in one set may be the same as another value in another set (but not necessarily), however, each set as a whole is generally not identical to any other set.

The processing unit 12 is configured to provide the different parameter value sets to the filter 18 for the filter 18 to operate according to the different parameter value sets (block 304). For example, parameter value set A is provided to the filter 18, and the network device 10 operates for a period of time with the provided parameter value set yielding a given performance of the network device 10 with respect to the error signal 38. Then parameter value set B is provided to the filter 18, and the network device 10 operates for a period of time with the provided parameter value set yielding another performance of the network device 10 with respect to the error signal 38, and so on.

The processing unit 12 is configured to receive measurements of error between the received remote clock and the local clock for corresponding ones of the different parameter value sets (block 306). For example, the processing unit 12 is configured to receive a measurement of error A, e.g., based on error signal 38, while the filter 18 is using parameter value set A, and receive a measurement of error B, e.g., based on error signal 38, while the filter 18 is using parameter value set B, and so on. The measurements of error may be based on root mean square (RMS) error measurements of corresponding sections of error signal 38 between the received remote clock and the local clock. For example, the measurement of error A may be based on the RMS of the error signal 38 while filter 18 is using parameter value set A.

The processing unit 12 is configured to build a model (e.g., fit a probabilistic model) based on the received measurements of error and the corresponding different parameter value sets (block 308) and build an acquisition function from the model (block 310). In some embodiments, the model is a Gaussian Process (GP) model. The acquisition function controls a tradeoff between exploration and exploitation phases and provides a parameter value set for the filter 18 to use next. There are different sampling strategies e.g., PI, EI, UCB, for sampling the GP model, described in more detail below. Probability of Improvement (PI) favors points with a high probability of improvement over the current best observation, so that PI(x)=P(f(x)>best observed), where “best observed” is the best function value observed so far. Expected Improvement (EI) balances exploration and exploitation by considering both the improvement over the current best observation and the uncertainty of the GP model, so that EI(x)=E[max(f(x)−best observed, 0)], where E [·] denotes the expected value. Upper Confidence Bound (UCB) balances exploration and exploitation by selecting points with high predicted mean values and high uncertainty, so that UCB (x)=μ(x)+κσ(x), where μ(x) is the mean predicted by the GP at point x, σ(x) is the standard deviation of the prediction, and k is a user-defined exploration parameter.

The processing unit 12 is configured to find a new parameter value set including one or more new parameter values of the filter parameter(s) based on (i.e., from) the acquisition function built in the step of block 310 (block 312). In some embodiments, the processing unit 12 is configured to select the new parameter value set based on statistics provided from the model. The processing unit 12 is configured to provide the new parameter value set to filter 18, and allow the filter 18 to operate according to the new parameter value set yielding a new measurement of error for the time period in which the filter 18 operated according to the new parameter value set. The processing unit 12 is configured to receive the new measurement of error between the received remote clock and the local clock for the new parameter value set (block 314). The processing unit 12 is configured to update the model based on the new measurement of error and the new parameter value set and update the acquisition function based on the updated model (block 316). The steps of blocks 312-316 may be repeated until a minimal error signal 38 is achieved or a given number of rounds (e.g., 20-25 iterations) are processed so that the processing unit 12 is configured to further improve the model based on further new parameter value sets and corresponding new measurements (block 318).

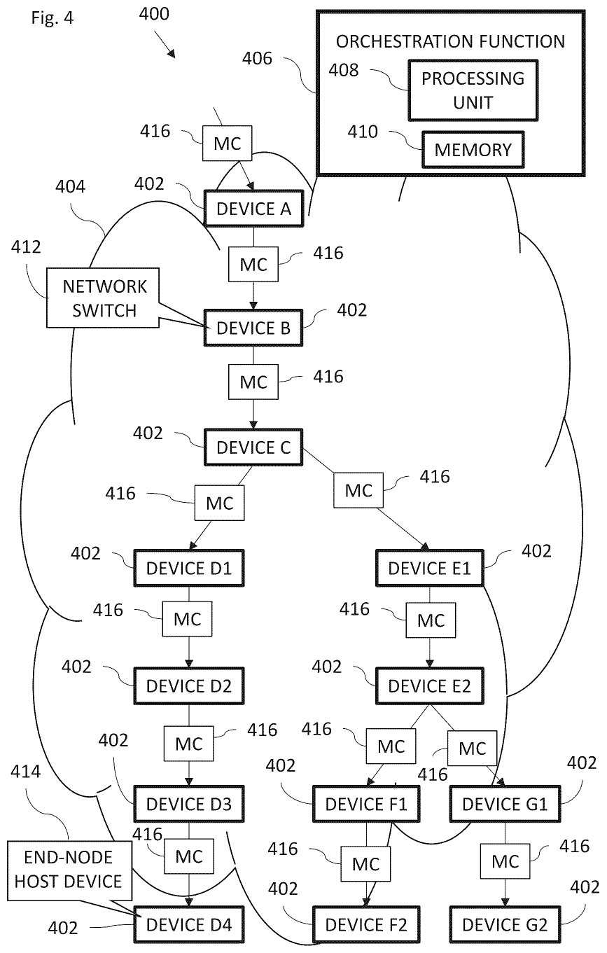

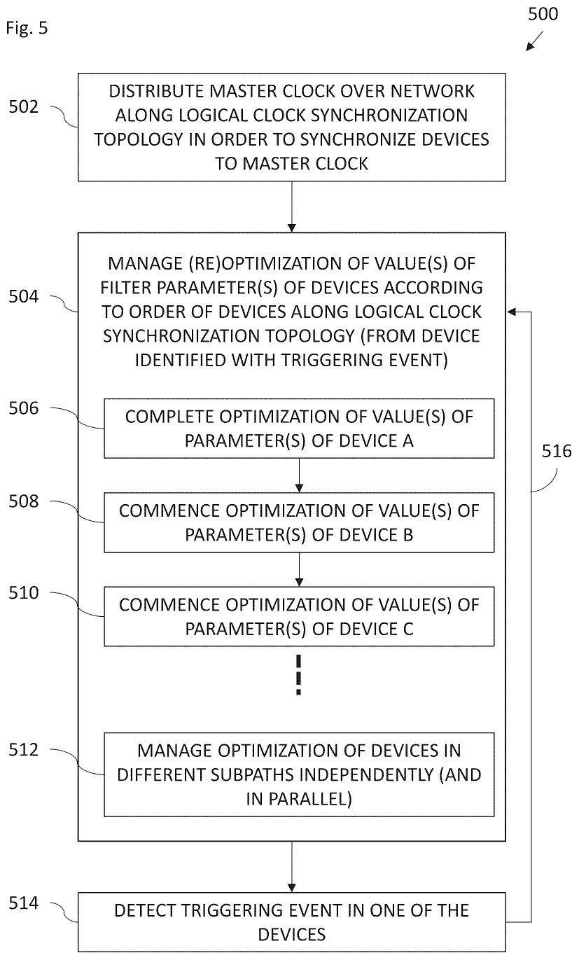

Reference is now made to FIGS. 4 and 5. FIG. 4 is a block diagram view of a clock synchronization system 400 constructed and operative in accordance with an embodiment of the present disclosure. FIG. 5 is a flowchart 500 including steps in a system-wide filter value optimization method in the system 400 of FIG. 4.

The system 400 includes a plurality of devices 402 connected via a network 404. The system 400 also includes an orchestration function 406, which may be included in one of the devices 402 or in its own device or in another device. In some embodiments, the functionality of the orchestration function 406 may be divided among the devices 402 and/or other devices. The orchestration function 406 includes at least one processing unit 408 and at least one memory 410. The memory (or memories) 410 is (are) configured to store data used by processing unit(s) 408. Devices 402 may include any one or more of the following: a network switch 412; or an end-node host device 414. Each device 402 may include one or more of the elements of network device 10 of FIG. 1 such as filter 18, and clock circuitry 16 including oscillator 22 and hardware clock 24. The filter parameter value(s) 40 of each device 402 may be optimized using any suitable optimization method, such as the Bayesian Optimization method described above with reference to FIGS. 1-3 or by using any suitable machine learning method such as a multiarmed bandit method.

Devices 402 are configured to distribute a master clock 416 over network 404 along a logical clock synchronization topology in order to synchronize the devices 402 to the master clock 416 (block 502). The logical clock synchronization topology is defined by the order in which the devices 402 share the master clock 416 from a root node (e.g., device A) of the logical clock synchronization topology to all the other nodes in the logical clock synchronization topology. In some embodiments, the logical clock synchronization topology includes sub-paths after a main clock synchronization path, as shown in the example of FIG. 4.

In the example of FIG. 4, device A receives master clock 416 from a clock leader (e.g., PTP grand master), and passes the master clock 416 to device B, which synchronizes to master clock 416. Device B passes master clock 416 to device C, which passes master clock 416 to devices D1 and E1. Device D1 passes master clock 416 to device D2, and device D2 to device D3, and device D3 to device D4. Device E1 passes master clock 416 to device E2, which passes master clock 416 to devices F1 and G1. Device F1 passes master clock 416 to device F2, and device G1 passes master clock 416 to device G2. Each device 402 which is “passed” the master clock 416 synchronizes to the master clock 416.

The processing unit 408 is configured to manage optimization of the value(s) of filter parameter(s) of respective ones of devices 402 according to an order of the devices 402 along the logical clock synchronization topology (block 504), generally while the master clock 416 is being distributed among the respective devices 402.

The step of block 504 may be illustrated using an example. As previously mentioned, device B is configured to clock synchronize to device A, and device C is configured to clock synchronize to device B. The processing unit 408 is configured to manage optimization of the value(s) of the filter parameter(s) of the respective devices 402 such that the processing unit 408 is configured to: complete optimization of the value(s) of the filter parameter(s) of device A (block 506), and then commence optimization of the value(s) of the filter parameter(s) of device B (block 508); and then commence optimization of the value(s) of the filter parameter(s) of device C after completion of the optimization of the value(s) of the filter parameter(s) of device B (block 510), and so on.

In some embodiments, the devices 402 may be optimized according to the order of the devices 402 along the logical clock synchronization topology such that the next device(s) 402 along the logical clock synchronization topology commences optimizing its own value(s) of the filter parameter(s) before the previous device 402 in the chain has completed optimizing its own value(s) of the filter parameter(s). For example, the processing unit 408 may be configured to manage optimization of the value(s) of the filter parameter(s) of the respective devices 402 such that the processing unit 408 is configured to: commence optimization of the value(s) of the filter parameter(s) of device A, and then commence optimization of the value(s) of the filter parameter(s) of device B (block 508); and then commence optimization of the value(s) of the filter parameter(s) of device C, and so on. In some embodiments, the processing unit 408 is configured to manage optimization of the value(s) of the filter parameter(s) of devices 402 on one sub-path independently of optimization of the value(s) of the filter parameter(s) of the devices 402 on a different one of the sub-paths. In some embodiments, the processing unit 408 is configured to optimize in parallel the value(s) of the filter parameter(s) of at least two of the devices 402 on a different sub-path (block 512). For example, device C may pass the master clock to devices D1 and E1, and device D1 is the first device in a first sub-path including devices D2 and D3, and device E1 is the first device in a second sub-path including device E2. In such a case, the value(s) of the filter parameter(s) of devices D1 and E1 may be optimized at the same time. Once the value(s) of the filter parameter(s) of device D1 are optimized, the value(s) of the filter parameter(s) of device D2 are optimized, and so on. Similarly, once the value(s) of filter parameter(s) of device E1 are optimized, the value(s) of the filter parameter(s) of device E2 are optimized, and so on. The timing and ordering of the optimization of the value(s) of the filter parameter(s) of devices in different sub-paths are independent of each other and may be parallelized, if possible. For example, the timing and ordering of the optimization of the value(s) of the filter parameter(s) of devices D1, D2, and D3 may be performed independently (i.e., irrespective of) the timing and ordering of the optimization of the value(s) of the filter parameters of devices E1, and E2.

In some embodiments, the devices 402 manage optimization by a given one of the devices 402 instructing the next downstream device(s) 402 to perform optimization of the value(s) of the filter parameter(s) once the given device 402 has completed its own optimization (or performed sufficient optimization) of the value(s) of the filter parameter(s), and so on.

The processing unit 408 of orchestration function 406 is configured to detect a triggering event in a given one of the devices 402 (e.g., device C) (block 514). The triggering event may include any suitable event, such as congestion, circuit degradation, and/or temperature change above a given limit or limits, for example. The processing unit 408 is configured to manage re-optimization of the value(s) of the filter parameter(s) of the given device (e.g., device C), and devices downstream from the given device (e.g., device D1, D2 etc., devices E1, E2, etc.) with respect to the logical clock synchronization topology, in response to the triggering event being identified in the given device by reperforming the step of block 504 (arrow 516). The re-optimization is managed according to the order of the given device and the downstream devices along the logical clock synchronization topology. In some embodiments, the triggering event may be detected by the device 402 in which the event was triggered (e.g., in device C) and that device 402 may report the event to orchestration function 406. In some embodiments, the device 402 in which the event was triggered instructs the next downstream device(s) 402 to perform re-optimization (without the need to involve orchestration function 406), and that next downstream device(s) 402 in turn instructs the next downstream device(s) 402 to perform re-optimization, and so on.

In practice, some or all of these functions of processing unit(s) 408 may be combined in a single physical component or, alternatively, implemented using multiple physical components. These physical components may comprise hard-wired or programmable devices, or a combination of the two. In some embodiments, at least some of the functions of processing unit(s) 408 may be carried out by a programmable processor under the control of suitable software. This software may be downloaded to a device in electronic form, over a network, for example. Alternatively, or additionally, the software may be stored in tangible, non-transitory computer-readable storage media, such as optical, magnetic, or electronic memory.

Some, or all, of the functions performed by the processing unit(s) 408 may be performed by one or more graphics processing units (GPUs) disposed in devices 402 or orchestration function 406. For example, the functions of filter 18 and/or the optimization of the value(s) of the parameter(s) may be performed by one or more GPUs.

The device(s) 10, 402, 406 may be any suitable device, such as: an accelerator device; a processing device including a central processing unit (CPU) and/or a graphics processing unit (GPU); a host device connected to one or more peripheral devices; a peripheral device connected to another peripheral device and/or one or more host devices; a network device, e.g., a network interface controller (NIC) device, a data processing unit (DPU) or smart NIC including a NIC and one or more processing cores, or a network switch. One or more of the processing steps described herein may be performed by a CPU, GPU, DPU, NIC, or any suitable combination thereof.

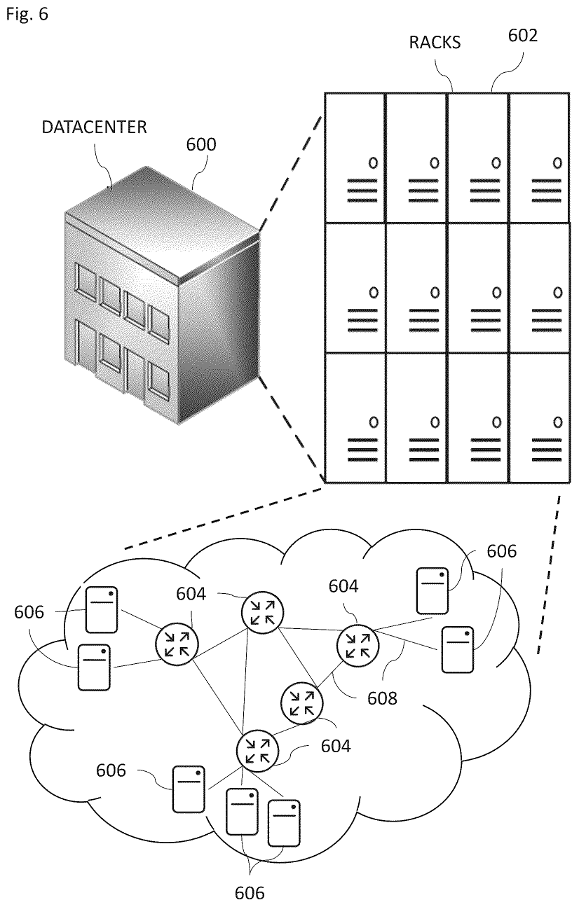

Reference is now made to FIG. 6, which is a schematic view of a datacenter 600 in the system 10 of FIG. 1 constructed and operative in accordance with an embodiment of the present disclosure. The device(s) 10, 402, 406 may be disposed in any suitable environment, such as datacenter 600. Datacenter 600 may include racks 602, which may include devices 402 such as network switches 604, and end-host devices 606, for example. The datacenter 600 may also include cooling systems, power supply, network components such as NICs (of end-host devices 606) and cabling 608 (only some labelled) to provide high-speed connectivity e.g., with multiple internet providers for redundancy, physical and cyber protections, including access controls and surveillance, organized spaces for servers and equipment. The data center may support remote storage and computing for cloud services.

The NIC may include any of the following: an Ethernet Port (RJ45 Connector), which is the physical interface where the network cable (usually an Ethernet cable) connects to the NIC and is used for wired network connections; packet processing hardware or circuitry, which is responsible for handling network communication and processes incoming and outgoing data packets and manages the network interface functions; a memory (such as RAM or ROM) to store temporary data, such as network packet buffers, configuration settings, and firmware, and helps in speeding up data transfer and processing; firmware, which is software programmed into the NIC's memory and controls the hardware operations and may perform firmware updates to improve performance or add new features to the NIC; LED Indicators that provide visual indicators of network status, common indicators including power status, network activity, and link speed; a bus Interface (e.g., PCI or PCIe) to connect the NIC to the host computer's motherboard; a processor to handle network processing tasks as well as other processing tasks to offload work from the main CPU of the host device and improve network performance; a heat sink or cooling mechanism (e.g., for high-performance NICs), especially those used in servers, to prevent overheating; power management circuitry to ensure the NIC receives the correct amount of power and manages power consumption efficiently; and/or connector pins and circuitry including internal connections and pathways that route signals between the NIC's components.

The packet processing hardware or circuitry is the central component of the NIC and handles network communications. It may include several key components that work together to manage and process network data, such as any one or more of the following: MAC (Media Access Control) Layer, which is responsible for handling the data link layer of the OSI model and manages how data packets are formatted, addressed, and transmitted over the network; MAC address register, which stores the unique hardware address (MAC address) of the NIC; a frame buffer that temporarily holds data frames as they are being processed; a PHY (Physical Layer) Interface that interfaces with the physical medium (such as Ethernet cables) and is responsible for the actual transmission and reception of data bits over the network; a transceiver that converts data between the digital signals used by the MAC layer and the analog signals used for transmission over the network medium; DMA (Direct Memory Access) Controller that manages data transfers between the NIC and the computer's memory without involving the CPU and helps to offload processing tasks from the CPU and improve data transfer efficiency; a packet Processing Engine that handles the encapsulation and decapsulation of network packets, and processes incoming and outgoing packets, managing tasks like error checking and packet filtering; buffer management, which includes memory areas for storing packets temporarily, such as transmit buffers to store packets that are being sent from the computer to the network, receive buffers to store packets received from the network before they are processed by the system; an interrupt controller that manages and generates interrupts to notify the CPU of events such as packet reception or transmission completion and helps in efficient handling of network events; a clock generator, which provides timing signals for the various components of the NIC to synchronize their operations; a power management unit to regulate power consumption and manages power-saving features of the NIC chip to improve energy efficiency; error handling and correction logic, which detects and corrects errors in data transmission and reception, and may include features for error-checking protocols like CRC (Cyclic Redundancy Check); configuration registers that store configuration settings and parameters that control the NIC's operation, such as speed settings, interrupt configurations, and buffer sizes; firmware/ROM that contains the embedded software that controls the NIC's operations and manages network protocols.

The network switch may include any of the following: ports where network cables connect; switching fabric that manages data transfer between ports; a MAC address table that stores device addresses and port information; a forwarding engine that directs data packets to the correct ports; buffer memory that temporarily holds data to manage traffic; a management processor that handles configuration and monitoring in managed switches; a power supply that provides electrical power; a cooling system that keeps the switch from overheating; firmware that controls the switch; LED Indicators that show status and activity; and networking modules (in modular switches) that allow for additional ports or features.

Regarding the graphics processing unit, graphics processing units (GPUs) are employed to generate three-dimensional (3D) graphics objects and two-dimensional (2D) graphics objects for a variety of applications, including feature films, computer games, virtual reality (VR) and augmented reality (AR) experiences, mechanical design, and/or the like. A modern GPU includes texture processing hardware to generate the surface appearance, referred to herein as the “surface texture,” for 3D objects in a 3D graphics scene. The texture processing hardware applies the surface appearance to a 3D object by “wrapping” the appropriate surface texture around the 3D object. This process of generating and applying surface textures to 3D objects results in a highly realistic appearance for those 3D objects in the 3D graphics scene.

The texture processing hardware is configured to perform a variety of texture-related instructions, including texture operations and texture loads. The texture processing hardware generates accesses texture information by generating memory references, referred to herein as “queries,” to a texture memory. The texture processing hardware retrieves surface texture information from the texture memory under varying circumstances, such as while rendering object surfaces in a 3D graphics scene for display on a display device, while rendering 2D graphics scene, or during compute operations.

Surface texture information includes texture elements (referred to herein as “texels”) used to texture or shade object surfaces in a 3D graphics scene. The texture processing hardware and associated texture cache are optimized for efficient, high throughput read-only access to support the high demand for texture information during graphics rendering, with little or no support for write operations. Further, the texture processing hardware includes specialized functional units to perform various texture operations, such as level of detail (LOD) computation, texture sampling, and texture filtering.

In general, a texture operation involves querying multiple texels around a particular point of interest in 3D space, and then performing various filtering and interpolation operations to determine a final color at the point of interest. By contrast, a texture load typically queries a single texel, and returns that directly to the user application for further processing. Because filtering and interpolating operations typically involve querying four or more texels per processing thread, the texture processing hardware is conventionally built to accommodate generating multiple queries per thread. For example, the texture processing hardware could be built to accommodate up to four texture memory queries performed in a single memory cycle. In that manner, the texture processing hardware is able to query and receive most or all of the needed texture information in one memory cycle.

In practice, some or all of these functions may be combined in a single physical component or, alternatively, implemented using multiple physical components. These physical components may comprise hard-wired or programmable devices, or a combination of the two. In some embodiments, at least some of the functions of the processing circuitry may be carried out by a programmable processor under the control of suitable software. This software may be downloaded to a device in electronic form, over a network, for example. Alternatively, or additionally, the software may be stored in tangible, non-transitory computer-readable storage media, such as optical, magnetic, or electronic memory.

The implementation of the method and/or system of examples of the disclosure can involve performing or completing selected tasks manually, automatically, or a combination thereof. Moreover, according to actual instrumentation and equipment of examples of the method and/or system of the disclosure, several selected tasks could be implemented by hardware, by software or by firmware or by a combination thereof using an operating system or a cloud-based platform.

For example, hardware for performing selected tasks according to examples of the disclosure could be implemented as a chip or a circuit. As software, selected tasks according to examples of the disclosure could be implemented as a plurality of software instructions being executed by a computer using any suitable operating system. In an exemplary example of the disclosure, one or more tasks according to exemplary examples of method and/or system as described herein are performed by a data processor, such as a computing platform for executing a plurality of instructions. Optionally, the data processor includes a volatile memory for storing instructions and/or data and/or a non-volatile storage, for example, non-transitory storage media such as a magnetic hard-disk and/or removable media, for storing instructions and/or data. Optionally, a network connection is provided as well. A display and/or a user input device such as a keyboard or mouse are optionally provided as well.

For example, any combination of one or more non-transitory computer readable (storage) medium(s) may be utilized in accordance with the above-listed examples of the present disclosure. The non-transitory computer readable (storage) medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store, a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

As will be understood with reference to the paragraphs and the referenced drawings, provided above, various examples of computer-implemented methods are provided herein, some of which can be performed by various examples of apparatuses and systems described herein and some of which can be performed according to instructions stored in non-transitory computer-readable storage media described herein. Still, some examples of computer-implemented methods provided herein can be performed by other apparatuses or systems and can be performed according to instructions stored in computer-readable storage media other than that described herein, as will become apparent to those having skill in the art with reference to the examples described herein. Any reference to systems and computer-readable storage media with respect to the following computer-implemented methods is provided for explanatory purposes, and is not intended to limit any of such systems and any of such non-transitory computer-readable storage media with regard to examples of computer-implemented methods described above. Likewise, any reference to the following computer-implemented methods with respect to systems and computer-readable storage media is provided for explanatory purposes, and is not intended to limit any of such computer-implemented methods disclosed herein.

The flowchart and block diagrams in the Figures illustrate the architecture, functionality, and operation of possible implementations of systems, methods and computer program products according to various examples of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, block diagrams and/or flowchart illustration, and combinations of blocks in the block diagrams and/or flowchart illustration, can be implemented by special purpose hardware-based systems that perform the specified functions or acts, or combinations of special purpose hardware and computer instructions. The descriptions of the various examples of the present disclosure have been presented for purposes of illustration, but are not intended to be exhaustive or limited to the examples disclosed. Many modifications and variations will be apparent to those of ordinary skill in the art without departing from the scope and spirit of the described examples.

As used herein, the singular form “a”, “an” and “the” include plural references unless the context clearly dictates otherwise.

It is appreciated that certain features of the disclosure, which are, for clarity, described in the context of separate examples, may also be provided in combination in a single example. Conversely, various features of the disclosure, which are, for brevity, described in the context of a single example, may also be provided separately or in any suitable sub-combination or as suitable in any other described example of the disclosure. Certain features described in the context of various examples are not to be considered essential features of those examples, unless the example is inoperative without those elements.

The above-described processes including portions thereof can be performed by software, hardware and combinations thereof. These processes and portions thereof can be performed by computers, computer-type devices, workstations, cloud-based platforms, processors, micro-processors, other electronic searching tools and memory and other non-transitory storage-type devices associated therewith. The processes and portions thereof can also be embodied in programmable non-transitory storage media, for example, compact discs (CDs) or other discs including magnetic, optical, etc., readable by a machine or the like, or other computer usable storage media, including magnetic, optical, or semiconductor storage, or other source of electronic signals.

The processes (methods) and systems, including components thereof, herein have been described with exemplary reference to specific hardware and software. The processes (methods) have been described as exemplary, whereby specific steps and their order can be omitted and/or changed by persons of ordinary skill in the art to reduce these examples to practice without undue experimentation. The processes (methods) and systems have been described in a manner sufficient to enable persons of ordinary skill in the art to readily adapt other hardware and software as may be needed to reduce any of the examples to practice without undue experimentation and using conventional techniques.

Various features of the disclosure which are, for clarity, described in the contexts of separate embodiments may also be provided in combination in a single embodiment. Conversely, various features of the disclosure which are, for brevity, described in the context of a single embodiment may also be provided separately or in any suitable sub-combination.

The embodiments described above are cited by way of example, and the present disclosure is not limited by what has been particularly shown and described hereinabove. Rather the scope of the disclosure includes both combinations and sub-combinations of the various features described hereinabove, as well as variations and modifications thereof which would occur to persons skilled in the art upon reading the foregoing description and which are not disclosed in the prior art.

What is claimed is:

1. A device, comprising:
a processing unit to:
find at least one value of at least one filter parameter using Bayesian Optimization; and
provide the at least one value of the at least one filter parameter to a filter to generate an adjustment to cause clock circuitry to adjust a local clock signal or local clock based on an error signal and the at least one value of the at least one filter parameter; and
a memory to store data used by the processing unit.

2. The device according to claim 1, further comprising:
the clock circuitry including:
an oscillator to generate the local clock signal having a clock frequency; and
a hardware clock to maintain the local clock based on the local clock signal;
the filter to:
receive the error signal between a received remote clock and the local clock; and
generate the adjustment to cause the clock circuitry to adjust the local clock signal or the local clock based on the error signal and the at least one value of the at least one filter parameter.

3. The device according to claim 1, wherein:
the clock circuitry includes:
an oscillator to generate the local clock signal having a clock frequency; and
a hardware clock to maintain the local clock based on the local clock signal;
the filter is to:
receive the error signal between a received remote clock and the local clock; and
generate an adjustment to cause the clock circuitry to adjust the local clock signal or the local clock based on the error signal and the at least one value of the at least one filter parameter.

4. The device according to claim 1, wherein the processing unit is to dynamically change the at least one value of the at least one filter parameter in order to find the at least one value of the at least one filter parameter which improves the adjustment of the local clock signal or local clock.

5. The device according to claim 1, wherein the processing unit is to:
select different parameter value sets, each parameter value set including at least one respective filter parameter value;
provide the different parameter value sets to the filter for the filter to operate according to the different parameter value sets;
receive measurements of error between a received remote clock and the local clock for corresponding ones of the different parameter value sets;
build a model based on the received measurements of error and the corresponding different parameter value sets;
build an acquisition function from the model;
find a new parameter value set including at least one new parameter value of the at least one filter parameter based on the acquisition function;
receive a new measurement of error between the received remote clock and the local clock for the new parameter value set;
update the model based on the new measurement of error and the new parameter value set; and
further improve the model based on further new parameter value sets and corresponding new measurements.

6. The device according to claim 5, wherein the processing unit is to select the new parameter value set based on statistics provided from the model.

7. The device according to claim 5, wherein the model is a Gaussian Process model.

8. The device according to claim 5, wherein the measurements of error are root mean square error measurements of corresponding sections of an error signal between the received remote clock and the local clock.

9. A system, comprising:
at least one processing unit to manage optimization of at least one value of at least one filter parameter of respective ones of devices according to an order of the devices along a logical clock synchronization topology; and
at least one memory to store data used by the at least one processing unit, wherein:
the devices are to distribute a master clock over a network along the logical clock synchronization topology in order to synchronize the devices to the master clock; and
each of the devices includes:
clock circuitry including: an oscillator to generate a local clock signal having a clock frequency; and a hardware clock to maintain a local clock based on the local clock signal; and
a filter to: receive an error signal between a received remote clock and the local clock; and generate an adjustment to cause the clock circuitry to adjust the local clock signal or the local clock based on the error signal and the at least one value of the at least one filter parameter.

10. The system according to claim 9, further comprising the devices.

11. The system according to claim 9, wherein:
the devices include a first device, a second device, and a third device;
the second device is to clock synchronize to the first device;
the third device is to clock synchronize to the second device; and
the at least one processing unit is to manage optimization of the at least one filter parameter of the respective devices such that the at least one processing unit is to:
complete optimization of the at least one value of the at least one filter parameter of the first device; and then
commence optimization of the at least one value of the at least one filter parameter of the second device; and then
commence optimization of the at least one value of the at least one filter parameter of the third device after completion of optimization of the optimization of the at least one value of the at least one filter parameter of the second device.

12. The system according to claim 11, wherein the third device is an end-node host device.

13. The system according to claim 9, wherein:
the devices include a first device, a second device, and a third device;
the second device is to clock synchronize to the first device;
the third device is to clock synchronize to the second device; and
the at least one processing unit is to manage optimization of the at least one filter parameter of the respective devices such that the at least one processing unit is to:
commence optimization of the at least one value of the at least one filter parameter of the first device; and then
commence optimization of the at least one value of the at least one filter parameter of the second device; and then
commence optimization of the at least one value of the at least one filter parameter of the third device.

14. The system according to claim 9, wherein:
the logical clock synchronization topology includes sub-paths after a main clock synchronization path; and
the at least one processing unit is to manage optimization of the at least one value of the at least one filter parameter of the devices on one of the sub-paths independently of optimization of the at least one value of the at least one filter parameter of the devices on a different one of the sub-paths.

15. The system according to claim 14, wherein the at least one processing unit is to optimize in parallel the at least one value of the at least one filter parameter of at least two of the devices on different ones of the sub-paths.

16. The system according to claim 9, wherein the devices include any one or more of the following: a network switch; or an end-node host device.

17. The system according to claim 9, wherein the at least one processing unit it to manage re-optimization of the at least one value of the at least one filter parameter of a given device of the devices, and ones of the devices downstream from the given device with respect to the logical clock synchronization topology, in response to a triggering event being identified in the given device, the re-optimization being managed according to the order of the given device and the downstream devices along the logical clock synchronization topology.

18. The system according to claim 9, wherein the at least one processing unit is to manage the optimization of the at least one value of the at least one filter parameter of the respective devices while the master clock is being distributed among the respective devices.

19. The system according to claim 9, wherein the at least one processing unit is optimize the at least one value of the at least one filter parameter of the respective devices using Bayesian Optimization.

20. A method, comprising:
finding at least one value of at least one filter parameter using Bayesian Optimization; and
providing the at least one value of the at least one filter parameter to a filter to generate an adjustment to cause clock circuitry to adjust a local clock signal or local clock based on an error signal and the at least one value of the at least one filter parameter.

21. A method, comprising:
managing optimization of at least one value of at least one filter parameter of respective ones of devices according to an order of the devices along a logical clock synchronization topology; and
distributing a master clock over a network along the logical clock synchronization topology in order to synchronize the devices to the master clock.
